(19) United States
(12) Patent Application Publication
(10) Pub. No.: US 2026/0026101 A1
(43) Pub. Date: Jan. 22, 2026

(54) FDSOI STRUCTURES AND METHODS FOR PREPARING FDSOI STRUCTURES

(71) Applicant: GlobalWafers Co., Ltd., Hsinchu (TW)

(72) Inventor: Qingmin Liu, Glen Carbon, IL (US)

(21) Appl. No.: 19/273,502

(22) Filed: Jul. 18, 2025

Related U.S. Application Data
(60) Provisional application No. 63/673,555, filed on Jul. 19, 2024.

(51) Int. Cl. H10D 86/01; H01L 21/762; H10D 86/00

(52) U.S. Cl. CPC H10D 86/01; H01L 21/76254; H10D 86/201

(57) ABSTRACT

Fully-depleted silicon-on-insulator structures and methods for preparing fully-depleted silicon-on-insulator structures. The fully-depleted silicon-on-insulator structure may include a top layer, a handle structure and a dielectric layer disposed between the silicon top layer and handle structure. The dielectric layer of the silicon-on-insulator structure may be composed of hafnia, zirconia, alumina, or combinations thereof. In some embodiments, the dielectric layer is relatively thick such as at least 20 nm or even at least 50 nm.

### CROSS-REFERENCE TO RELATED APPLICATIONS

This application claims the benefit of U.S. Provisional Patent Application No. 63/673,555, filed Jul. 19, 2024, which is incorporated herein by reference in its entirety.

### TECHNICAL FIELD

The field of the disclosure relates to fully-depleted silicon-on-insulator structures and methods for preparing fully-depleted silicon-on-insulator structures.

### BACKGROUND

Silicon top layer thickness uniformity, defectivity and roughness are important for fully depleted silicon-on-insulator (FDSOI) processes. Conventional methods for producing FDSOI involve thinning the silicon top layer which degrades thickness uniformity.

Conventional FDSOI may also involve an argon or hydrogen smoothing process. Argon smoothing may result in dewetting in which the top silicon dewets the dielectric and pulls back into the film edge causing a local increase in thickness. Thin thicknesses at the edge (either through a starting thin thickness or localized etching during the anneal) become unstable during the anneal which leads to dewetting. Dewetting is caused by the following reaction:

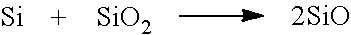

with SiO evaporating in the anneal furnace.

Defectivity is also an issue in FDSOI processes. Since the dielectric layer is only about 20 nm, more gases collect at the bond interface during the bond-treatment step (instead of being absorbed in the dielectric layer as in other structures with thicker dielectric layers) to weaken the bond strength that results in pull-out defects in the subsequent mechanical cleave step.

Also, during smoothing anneals it is difficult to increase the anneal temperature to further reduce the surface roughness due to dewetting.

A need exists for FDSOI structures and manufacturing processes for FDSOI that achieve good top silicon layer uniformity, defectivity, and surface roughness with reasonable yield and throughput.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a method for preparing a fully-depleted silicon-on-insulator structure. The fully-depleted silicon-on-insulator structure includes a silicon top layer, a handle structure, and dielectric layer disposed between the silicon top layer and handle structure. Ions are implanted into a donor structure to form a cleave plane in the donor structure. A handle structure is provided. A dielectric layer is formed on at least one of the donor structure and handle structure prior to bonding. The dielectric layer is composed of hafnia, zirconia, alumina, or combinations thereof. The donor structure is bonded to the handle structure to form a bonded wafer structure comprising the donor structure, handle structure and a dielectric layer disposed between the handle structure and the donor structure. The bonded wafer structure is cleaved at the cleave plane such that a portion of the donor structure remains bonded to the handle structure as a silicon top layer. The cleave forms a silicon-on-insulator structure comprising the handle structure, silicon top layer and dielectric layer disposed between the handle structure and silicon top layer. The silicon-on-insulator structure is annealed to smooth the silicon top layer and form a smoothed silicon-on-insulator structure. The smoothed silicon-on-insulator structure is cleaned to produce a cleaned silicon-on-insulator. The silicon top layer has a thickness of less than 15 nm after cleaning.

Another aspect of the present disclosure is directed to a fully-depleted silicon-on-insulator structure. The fully-depleted silicon-on-insulator structure includes a silicon top layer, a handle structure, and a dielectric layer disposed between the silicon top layer and handle structure. The silicon top layer has a thickness of less than 13 nm. The dielectric layer is made of hafnia, zirconia, alumina, or combinations thereof. The dielectric layer has a thickness of at least 20 nm.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a cross-section view of a donor structure having a donor wafer with a dielectric layer thereon;

FIG. 2 is cross-section view of the donor structure during ion implantation thereon;

FIG. 3 is a cross-section view of the donor structure bonded to a handle structure; and

FIG. 4 is a cross-section view of a bonded wafer structure upon cleaving the donor structure at the cleave plane.

Corresponding reference characters indicate corresponding parts throughout the drawings.

### DETAILED DESCRIPTION

Provisions of the present disclosure relate to fully-depleted silicon-on-insulator (FDSOI) structures and methods for producing fully-depleted silicon-on-insulator structures. Such SOI structures may include a handle wafer, a silicon layer (sometimes referred to as a “silicon device layer” or “silicon top layer”) and a dielectric layer disposed between the handle wafer and silicon layer. In such FDSOI structures, the relatively thin silicon top layer may be depleted (e.g., fully depleted) of free charge carriers when the transistor is off (i.e., the silicon top layer is depleted of electrons (in NMOS) or holes (in PMOS)). The following is merely one example of methods and systems for preparing a silicon-on-insulator structure and other methods may be used unless stated otherwise.

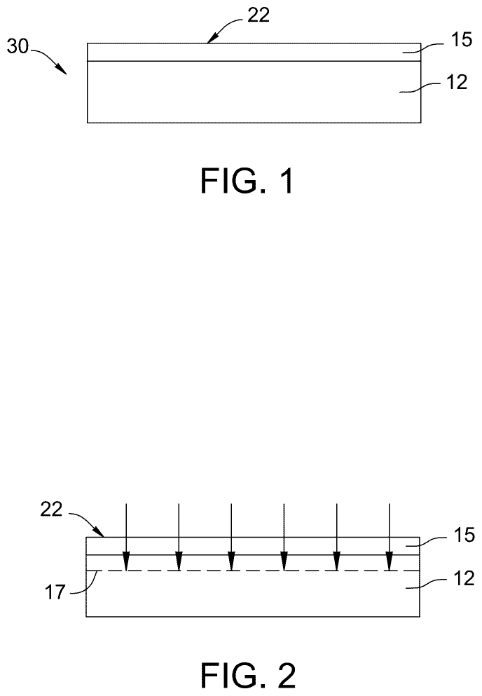

An example of a donor structure 30 that may be bonded to a handle structure to form a bonded wafer structure is shown in FIG. 1. The donor structure 30 may be formed with a dielectric layer 15 deposited on the front surface of a donor structure 12 (e.g., donor wafer 12). It should be understood that, alternatively, the dielectric layer 15 may be grown or deposited on the handle wafer or a dielectric layer may be grown on both the donor wafer and handle wafer and that these structures may be bonded in any of the various arrangements without limitation. Suitable donor wafers 12 may be composed of silicon, germanium, silicon germanium, gallium nitride, aluminum nitride, gallium arsenide, indium gallium arsenide and any combination thereof. In some embodiments, the donor wafer 12 is composed of single crystal silicon.

In accordance with embodiments of the present disclosure, the dielectric layer 15 is composed of hafnia (HfO₂), zirconia (ZrO₂), alumina (Al₂O₃), or combinations thereof. For example, the dielectric layer may include at least 50%, at least 65%, at least 80%, at least 95%, or at least 99% hafnia, zirconia, alumina, or combinations thereof. In some embodiments, the dielectric layer consists of or consists essentially of hafnia, zirconia, alumina, or combinations thereof.

The dielectric layer 15 may be applied according to any known technique in the art and, in some embodiments, is applied by atomic layer deposition (ALD). Atomic layer deposition involves sequential, self-limiting reactions on the surface of the substate which allows layer-by-layer deposition. Commercially available process tools for atomic layer deposition include batch ALD technology from Kokusai Electric (Tokyo, Japan) or from ALD tools from ASM (Almere, the Netherlands).

By using hafnia, zirconia, alumina, or combinations thereof, the dielectric layer 15 may be relatively thicker than conventional dielectric layers used for FDSOI. For example, the dielectric layer 15 may have a thickness of at least 20 nm, at least 30 nm, at least 40 nm, at least 50 nm, or from 20 nm to 100 nm, from 20 nm to 75 nm or from 40 nm to 75 nm.

As shown for example in FIG. 2, ions (e.g., hydrogen atoms, helium atoms or a combination of hydrogen and helium atoms) may be implanted at a substantially uniform specified depth beneath the front surface 22 of the donor structure to define a cleave plane 17. It should be noted that, when helium and hydrogen ions are co-implanted into the structure to form the cleave plane 17, they may be implanted concurrently or sequentially. In some embodiments, ions are implanted prior to deposition of the dielectric layer 15. When implantation is performed prior to deposition of the dielectric layer 15, the subsequent growth or deposition of the dielectric layer on the donor wafer 12 is suitably performed at a temperature low enough to prevent premature separation or cleaving along plane 17 in the donor layer (i.e., prior to the wafer bonding process step).

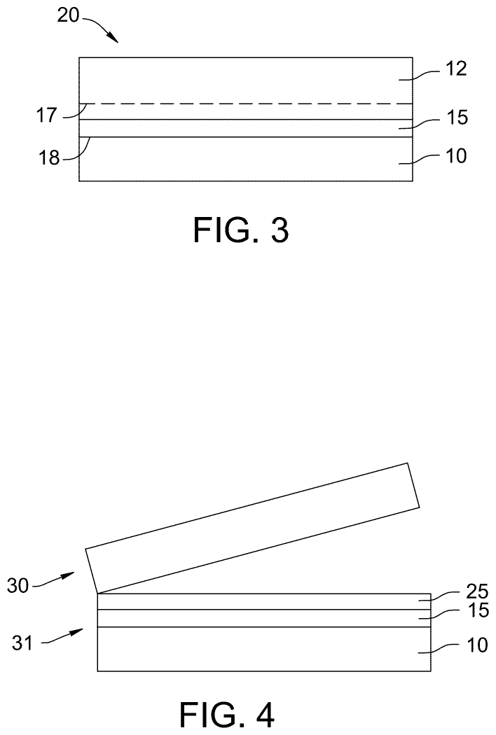

The handle structure 10 (FIG. 3) may include a handle wafer obtained from any suitable material for preparing multi-layered structures, such as silicon, silicon carbide, sapphire, germanium, silicon germanium, gallium nitride, aluminum nitride, gallium arsenide, indium gallium arsenide, quartz and combinations thereof. The handle structure 10 may include a dielectric layer (i.e., hafnia, zirconia, alumina, or combinations thereof) deposited on a handle wafer or, as in other embodiments, consists only of a handle wafer (i.e., does not include a dielectric layer). The handle wafer and donor wafer may be single crystal silicon wafers and may be single crystal silicon wafers which have been sliced from a single crystal ingot grown in accordance with conventional Czochralski crystal growing methods.

As shown in FIG. 3, the front surface of the dielectric layer 15 of the donor structure is suitably bonded to the front surface of the handle structure 10 to form a bonded wafer structure 20 through a bonding process. The dielectric layer 15 and handle structure 10 may be bonded together while performing a surface activation by exposing the surfaces of the structures to a plasma containing, for example, oxygen or nitrogen (i.e., plasma activation process). The wafers are then pressed together and a bond at the bond interface 18 is formed therebetween. Generally speaking, wafer bonding may be achieved using essentially any technique known in the art, provided the energy employed to achieve formation of the bond interface is sufficient to ensure that the integrity of the bond interface is sustained during subsequent processing (i.e., layer transfer by separation along the cleave or separation plane 17 in the donor wafer).

Once prepared, the bonded wafer structure 20 is placed in the cleaving device to separate (i.e., cleave) a portion of the donor wafer along the cleave plane from the bonded structure to form the layered semiconductor structure (e.g., SOI structure). Generally speaking, the cleaving device may induce this fracture using techniques known in the art, such as thermally and/or mechanically induced cleaving techniques.

Referring to FIG. 4, upon separation, two structures 30, 31 are formed. Because the separation of the bonded wafer structure 20 occurs along the cleave plane 17 in the donor structure 12 (FIG. 2), a portion of the donor structure remains part of both structures (i.e., a portion of the donor wafer is transferred along with the dielectric layer 15). Structure 30 comprises a portion of the donor wafer. Structure 31 is the SOI structure and includes a handle structure 10, dielectric layer 15 and silicon top layer 25 (the portion of the donor wafer remaining after cleaving) disposed atop the dielectric layer 15. In embodiments in which the donor structure and handle structure both include a dielectric layer, the dielectric layers combine to form the dielectric layer 15 of the SOI structure.

In some embodiments, a relatively shallow-implant is used such that the as-cleave silicon top layer has a thickness of less than 50 nm (e.g., 40-50 nm). The SOI structure 31 may have any radius (e.g., about 100 mm, about 150 mm or more) unless stated otherwise.

The cleaving device used to separate the bonded wafer structure along the cleave plane may be a mechanical cleaving device in which separation is induced or achieved by means of mechanical force, either alone or in addition to annealing. For instance, the bonded structure may be placed in a fixture in which mechanical force is applied perpendicular to the opposing sides of the bonded structure in order to pull a portion of the donor structure apart from the bonded structure.

An example cleaving device includes suction cups that apply mechanical force near a leading cleave edge of the bonded wafer structure 20. The separation of the portion of the donor wafer may be initiated by applying a mechanical wedge or blade at the edge of the bonded wafer at the cleave plane 17 in order to initiate propagation of a crack along the cleave plane 17. The mechanical force applied by the suction cups then pulls the portion of the donor structure from the bonded structure, thus forming the SOI structure. Mechanical cleaving devices are commercially available such as the Debond & Cleave Tools from Silicon Genesis Corporation (San Jose, California).

In alternative embodiments, the cleaving device is a thermal cleaving device in which fracturing is achieved by annealing the bonded structure. For example, a thermal cleave may performed at a temperature about 200° C. to about 800° C., or from about 250° C. to about 650° C. for a period of at least about 10 seconds, at least about 1 minute, at least about 15 minutes, at least about 1 hour or even at least about 3 hours (with higher temperatures requiring shorter anneal times, and vice versa), under an inert (e.g., argon or nitrogen) atmosphere or ambient conditions. The thermal cleaving device may be a belt furnace in which propagation of the cleave is achieved at the leading edge of the bonded structure (i.e., the leading edge in the direction of travel of the structure through the furnace) and proceeds toward the trailing edge of the bonded wafer structure. Other types of cleaving devices may also be used.

After cleaving, the silicon top layer of the silicon-on-insulator structure may be thinned (i.e., prior to the smoothing anneal discussed below). Thinning may be performed by thermally growing a relatively thick SiO₂ layer (e.g., about 300 nm) on the top surface and stripping the SiO₂ in HF (“layer thinning process”). The thinning process may remove 10 to 30 nm of the implant damaged silicon top layer.

The cleave surface of the SOI structure 31 (i.e., the thin device layer 25 of the donor wafer) has a rough surface that may be smoothed by additional processing. The structure 31 may be subjected to additional processing to produce a layer surface having desirable features for device fabrication thereon and/or for deposition of a thickening epitaxial layer.

In accordance with some embodiments of the present disclosure, the silicon-on-insulator structure 31 is subjected to a smoothing anneal to form a smoothed silicon-on-insulator structure. The smoothing anneal reorders the silicon on the top surface of the silicon device layer 25 of the structure 31. Without being bound to any particular theory, the smoothing anneal also strengthens the oxide to oxide bond between the handle structure 10 and the silicon device layer 25 (i.e., in embodiments in which the handle and donor wafers include an oxide on their bonding surfaces).

In some embodiments, the smoothing anneal of the silicon-on-insulator structure 31 is performed at a temperature of at least about 1000° C. (e.g., about 1000° C. to about 1200° C.). The length of the anneal may vary (e.g., 0.5 hours to 16 hours), with higher anneal temperatures corresponding to lower anneal periods and vice versa. Example ambients include argon and hydrogen.

After the smoothing anneal, the silicon top layer 25 of the smoothed silicon-on-insulator structure may be cleaned. For example, a single wafer cleaner using HF/O₃ chemistry may be used. The clean may further reduce the thickness of the silicon top layer 25. For example, after cleaning, the silicon top layer may have a thickness of less than 15 nm or less than 13 nm after cleaning (e.g., less than 15 nm and at least 8 nm, less than 15 nm and at least 9 nm or less than 13 nm and at least 10 nm after cleaning).

In some embodiments, the donor structure 12 may be pre-bond annealed before bonding the donor structure 12 to the handle structure 10 to allow the implanted gasses to diffuse. For example, the pre-bond anneal may be at a temperature between 100° C. and 300° C. (e.g., 250° C. to 300° C.) and be performed for at least 30 minutes (e.g., 30 minutes to 4 hours) and may be performed at atmospheric pressure. When a relatively thicker dielectric layer 15 is used (such as at least 50 nm), the pre-bond anneal may be eliminated (i.e., without a pre-bond annealed before bonding the donor structure 12 to the handle structure 10).

By use of hafnia, zirconia, or alumina, dewetting during smoothing may be reduced or eliminated which allows for a thinner silicon top layer 25 to be achieved during smoothing. Accordingly, in some embodiments, the wafer thinning process described above may be eliminated (e.g., when dielectric thicknesses of at least 50 nm are used).

Compared to conventional methods and SOI structures, the methods and structures of the present disclosure have several advantages. Hafnia, zirconia, or alumina dielectric layers (i.e., material with a high-K value relative to SiO₂) allows a thicker dielectric layer to be used (e.g., at least 50 nm). Increasing the thickness of the dielectric layer allows the same backside bias to be achieved (relative to SiO₂) and improved defectivity for layer transfer. Use of hafnia, zirconia, or alumina dielectric layers improves silicon top layer uniformity and surface roughness.

By replacing the dielectric layer with a high-k material such as hafnia, zirconia, or alumina, dewetting may be prevented or significantly reduced to allow a thinner top silicon layer to be used in the smoothing anneal process. The subsequent layer thinning process may be eliminated without degrading the top silicon layer thickness uniformity. Without dewetting, higher smoothing anneal temperatures may be used to further reduce the surface roughness.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A method for preparing a fully-depleted silicon-on-insulator structure comprising a silicon top layer, a handle structure, and dielectric layer disposed between the silicon top layer and handle structure, the method comprising:
implanting ions into a donor structure to form a cleave plane in the donor structure;
providing a handle structure;
forming a dielectric layer on at least one of the donor structure and handle structure prior to bonding, the dielectric layer being composed of hafnia, zirconia, alumina, or combinations thereof;
bonding the donor structure to the handle structure to form a bonded wafer structure comprising the donor structure, handle structure and a dielectric layer disposed between the handle structure and the donor structure;
cleaving the bonded wafer structure at the cleave plane such that a portion of the donor structure remains bonded to the handle structure as a silicon top layer, the cleave forming a silicon-on-insulator structure comprising the handle structure, silicon top layer and dielectric layer disposed between the handle structure and silicon top layer;
annealing the silicon-on-insulator structure to smooth the silicon top layer and form a smoothed silicon-on-insulator structure; and
cleaning the smoothed silicon-on-insulator structure to produce a cleaned silicon-on-insulator, the silicon top layer having a thickness of less than 15 nm after cleaning.

2. The method as set forth in claim 1 wherein the dielectric layer has a thickness of at least 20 nm.

3. The method as set forth in claim 1 wherein the dielectric layer has a thickness of at least 50 nm, the donor structure not being pre-bond annealed before bonding the donor structure to the handle structure.

4. The method as set forth in claim 1 wherein the donor structure is pre-bond annealed before bonding the donor structure to the handle structure.

5. The method as set forth in claim 1 wherein the dielectric layer is formed on at least one of the donor structure and handle structure by atomic layer deposition.

6. The method as set forth in claim 1 comprising thinning the silicon top layer of the silicon-on-insulator structure prior to annealing the silicon-on-insulator structure.

7. The method as set forth in claim 1 wherein the dielectric layer has a thickness of at least 50 nm, the silicon top layer of the silicon-on-insulator structure not being thinned prior to annealing the silicon-on-insulator structure to smooth the silicon top layer.

8. The method as set forth in claim 1 wherein the silicon top layer has a thickness of less than 13 nm after cleaning.

9. The method as set forth in claim 1 wherein the donor structure and/or handle structure are plasma activated prior to bonding the donor structure to the handle structure to form a bonded wafer structure.

10. The method as set forth in claim 1 wherein the dielectric layer is composed of hafnia.

11. The method as set forth in claim 1 wherein the dielectric layer is composed of zirconia.

12. The method as set forth in claim 1 wherein the dielectric layer is composed of alumina.

13. The method as set forth in claim 1 wherein the silicon-on-insulator structure is annealed in an atmosphere comprising argon or hydrogen to smooth the silicon top layer and form a smoothed silicon-on-insulator structure.

14. A fully-depleted silicon-on-insulator structure comprising:
a silicon top layer, the silicon top layer having a thickness of less than 13 nm;
a handle structure; and
a dielectric layer disposed between the silicon top layer and handle structure, the dielectric layer being made of hafnia, zirconia, alumina, or combinations thereof, the dielectric layer having a thickness of at least 20 nm.

15. The fully-depleted silicon-on-insulator structure as set forth in claim 14 wherein the dielectric layer has a thickness of at least 50 nm.

16. The fully-depleted silicon-on-insulator structure as set forth in claim 14 wherein the dielectric layer is composed of hafnia.

17. The fully-depleted silicon-on-insulator structure as set forth in claim 14 wherein the dielectric layer is composed of zirconia.

18. The fully-depleted silicon-on-insulator structure as set forth in claim 14 wherein the dielectric layer is composed of alumina.

19. The fully-depleted silicon-on-insulator structure as set forth in claim 14 wherein the dielectric layer is composed of a combination of hafnia, zirconia, and/or alumina.

20. The fully-depleted silicon-on-insulator structure as set forth in claim 14 wherein the dielectric layer consists essentially of hafnia, zirconia, alumina, or a combination thereof.
